(19) United States
(12) Patent Application Publication
(10) Pub. No.: US 2014/0024199 A1
(43) Pub. Date: Jan. 23, 2014

(54) SEMICONDUCTOR WAFER DICING METHOD

(71) Applicants: Shunan QIU, Trondheim (NO); Guoliang GONG, Tianjin (CN); Jun LI, Tianjin (CN); Haiyan LIU, Tianjin (CN)

(72) Inventors: Shunan QIU, Trondheim (NO); Guoliang GONG, Tianjin (CN); Jun LI, Tianjin (CN); Haiyan LIU, Tianjin (CN)

(21) Appl. No.: 13/681,401

(22) Filed: Nov. 19, 2012

(30) Foreign Application Priority Data
Jul. 18, 2012 (CN) 201210352749.3

(51) Int. Cl. H01L 21/82

(52) U.S. Cl. CPC H01L 21/82
USPC 438/462

(57) ABSTRACT

A method of producing semiconductor dies includes providing a semiconductor wafer having front and back faces and an array of integrated circuits fabricated on it. The integrated circuits having active faces at the front face of the wafer. Grooves are cut mechanically from the back face partially through the wafer along saw streets between the integrated circuits. The integrated circuits are then singulated by scanning a laser beam on the front face within and along the saw streets, which scribes the wafer from the front face, and then singulating the integrated circuits by mechanically cleaving the wafer along the saw streets.

### BACKGROUND OF THE INVENTION

The present invention is directed to semiconductor integrated circuits and, more particularly, to a method of dicing a semiconductor wafer.

Producing semiconductor devices involves fabricating an array of the integrated circuits in a semiconductor wafer. The wafer is typically formed from mono-crystalline semiconductor material, such as silicon, or from compound semiconductor materials. The active and passive elements of the circuits are formed in and on the wafer by steps such as deposition of metals, poly-crystalline semiconductor and other materials, epitaxial growth, etching, patterning, doping and oxidation. The integrated circuits may include electronic components and micro-electromechanical systems (MEMS), for example.

After fabrication of the array of integrated circuits, the wafer is diced to produce singulated semiconductor dies. The dicing operation consists of separating the semiconductor devices along orthogonal saw streets. Conventional dicing techniques include mechanical cutting, typically by sawing, laser cutting, and laser scribing. Continued progress in reduction of the size of the semiconductor dies with the same or increased functionality and complexity of the electronic circuits integrated in the dies means that the width of the saw streets may represent a significant reduction in the density of dies formed in the wafer. It would be desirable to reduce the width of the saw streets to allow for more area on the wafer to be used for forming circuitry.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. For example, certain vertical dimensions have been exaggerated relative to horizontal dimensions.

FIG. 1 is a schematic sectional view of a packaged semiconductor device including a semiconductor die produced using conventional singulation techniques;

FIGS. 2 and 3 are schematic sectional views of a wafer containing an array of integrated circuits at successive stages of conventional singulation techniques;

FIGS. 4 to 8 are schematic sectional views of a wafer containing an array of integrated circuits at successive stages of a singulation operation of a method of producing semiconductor dies in accordance with one embodiment of the invention, given by way of example; and

FIG. 9 is a flow chart of the method of producing semiconductor dies illustrated in FIGS. 4 to 8.

### DETAILED DESCRIPTION OF THE INVENTION

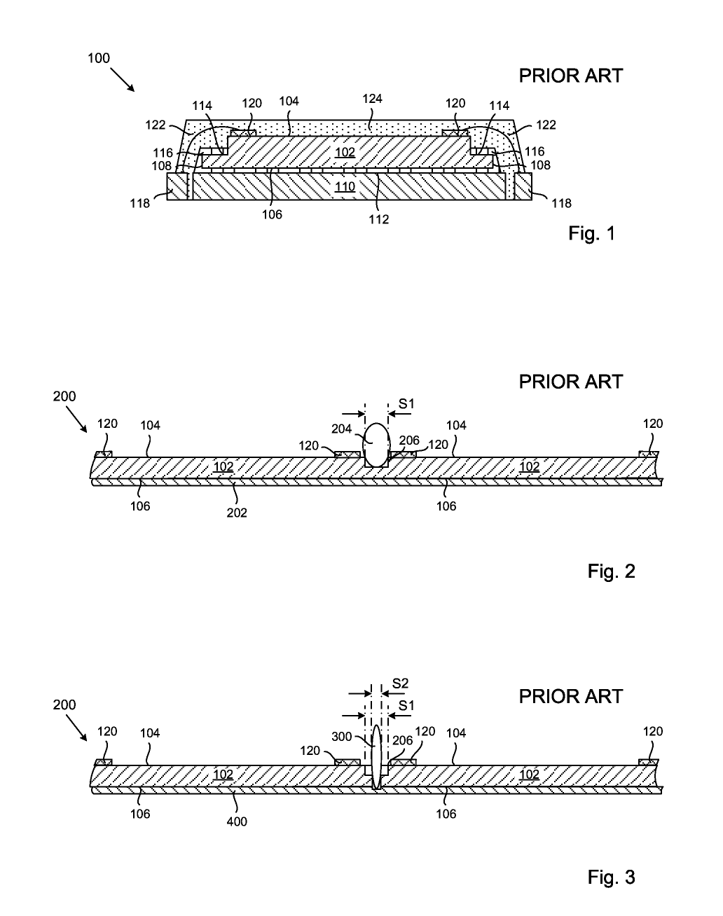

FIG. 1 illustrates one kind of packaged semiconductor device 100 including a semiconductor die 102 produced using a conventional singulation method. The semiconductor die 102 has an active face 104, a back face 106 and edges 108. The semiconductor device 100 also comprises a die support member 110, such as a thermally conductive flag of a lead frame, having a bonding surface 112. The semiconductor die 102 has a groove 114 at the edge 108 that is located in and around the active face 104. The back face 106 of the semiconductor die 102 is bonded to the bonding surface 112 of the die support member 110 with a die attach material wherein a fillet 116 of the die attach material is accommodated in the groove 114.

The packaged semiconductor device 100 includes a set of exposed electrical contact elements 118, which may be formed from part of a lead frame which also provides the die support 110. The active face 104 of the semiconductor die 102 has a plurality of electrical contact elements 120 that are electrically connected with the exposed electrical contact elements 118 such as with bond wires 122, which may be done using conventional wire bonding processes and equipment. A molding compound 124 covers the first face 104, fillet 116 and bond wires 122.

As shown in FIG. 2, producing the packaged semiconductor device 100 includes fabricating an array of semiconductor devices 102 in a wafer 200 with their active faces 104 at the front face of the wafer 200 and their back faces at the back face of the wafer 200. The front face of the wafer 200 bears alignment marks (not shown) that are used to align saw streets for the singulation process with the structure of the array of semiconductor devices in the wafer, the alignment marks being produced by processes used in fabricating the array of semiconductor devices and being aligned therewith. The wafer 200 is mounted with the back faces 106 of the semiconductor dies 102 on a backing 202 such as an adhesive support film.

The wafer 200 on the backing 202 is installed in a saw represented in the drawing by a first saw blade 204. The first saw blade 204 is used to make a first cut in the front face of the wafer 200 to form a groove 206 part way through the thickness of the wafer 200 in the active faces 104 of the semiconductor dies 102.

The first saw blade 204 is displaced along a set of parallel saw streets and an orthogonal set of parallel saw streets between adjacent semiconductor dies 102 to form the grooves 206. The displacement of the first saw blade 204 is guided by the alignment marks on the first face 104 of the wafer 200. A width S1 of the grooves 206 is defined by the width of the first saw blade 204. Each groove 206 will form the grooves 114 in the active faces 104 and edges 108 of adjacent semiconductor dies 102.

Referring to FIG. 3, the semiconductor dies 102 are then singulated with a second saw blade 300. That is, the first saw blade 204 is replaced with a second saw blade 300 and the second saw blade 300 is used to make a second cut along the same set of parallel saw streets and orthogonal set of parallel saw streets between adjacent semiconductor dies 102, again guided by the alignment marks on the front face of the wafer 200. The width S2 of the second saw blade 300 is less than the width S1 of the first saw blade 204. The second saw blade 300 cuts wholly through the remaining thickness of the wafer 200 in the grooves 206 from the same side as the active faces 104 of the semiconductor dies 102 to singulate the semiconductor dies 102. Each semiconductor die 102 is then attached to the bonding surface 112 of the die support member 110 with die attach adhesive, which flows into the groove 114, forming a fillet 116 which is received in the groove 114, as shown in FIG. 1.

The saw streets in the front face of the wafer 200 have a width that is greater than the kerf width S1 of the first saw blade 204 because of the positioning tolerances of the saw cut. In practice, with currently available techniques, it is difficult to reduce the wasted width of the saw streets to less than 40 μm, which represents a significant reduction in the area of the active faces of the dies in the wafer.

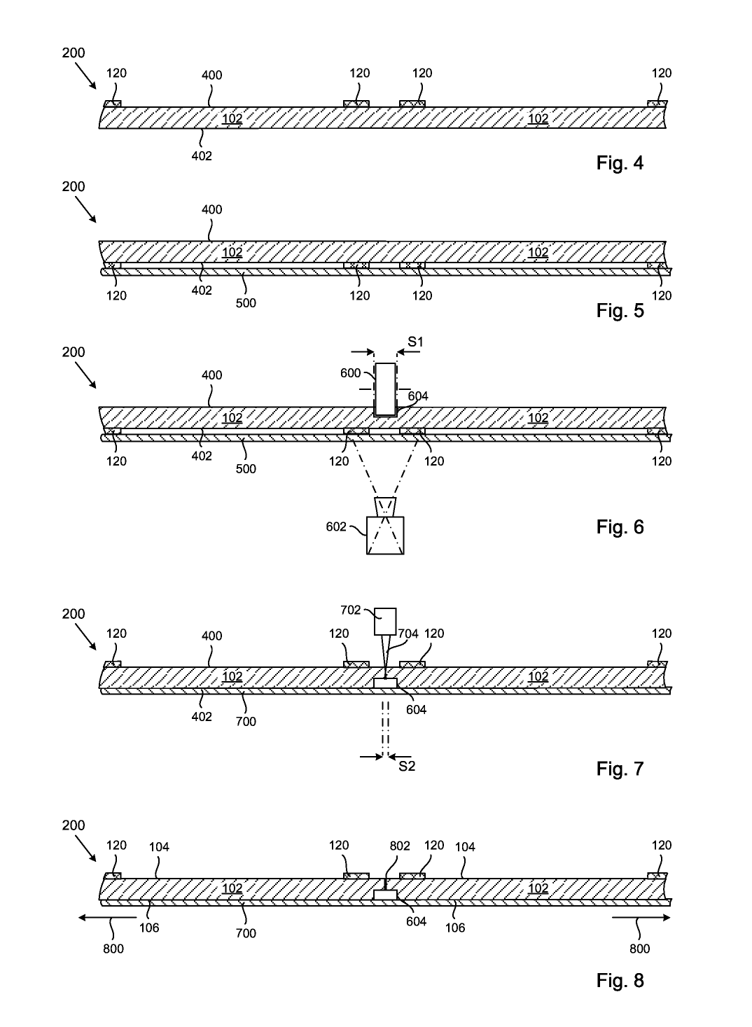

FIGS. 4 to 9 illustrate a method of producing semiconductor dies in accordance with an example of an embodiment of the invention. The method comprises providing a semiconductor wafer 200 having front and back faces 400 and 402 and an array of dies (integrated circuits) 102 fabricated therein. The dies (integrated circuits) 102 have active faces 104 at the front face 400 of the wafer. Grooves 604 are cut mechanically from the back face 402 partially through the wafer 200 along saw streets between the dies (integrated circuits) 102. The dies (integrated circuits) 102 are then singulated, the singulation including scanning a laser beam 704 onto the front face 400 within and along the saw streets.

The grooves 604 reduce the thickness of the wafer 200 in the saw streets so that the width S2 of the singulation and the wasted width of the saw streets can be substantially reduced. The width S1 of the grooves 604 does not reduce the area available for the active faces 104 of the dies (integrated circuits) 102, since the grooves 604 are cut from the back face 402 of the wafer 200 and are not cut through to the front face 400.

In one example of an embodiment of the method of the invention, scanning the laser beam 704 scribes the wafer 200 from the front face 400 and singulating the dies (integrated circuits) 102 includes loading the wafer 200 mechanically to cleave the wafer along the saw streets. Singulating the dies 102 includes mounting the wafer 200 with the back face 402 attached to a back face adhesive support element 700 after cutting the grooves 604. Loading the wafer 200 mechanically includes stretching the back face adhesive support element 700 radially to apply a radial tensile stress to the back face 402. In the operation of scribing the wafer 200, since the thickness of the wafer 200 is reduced by the grooves 604, the width S2 of the regions affected by the laser scans can be reduced.

In another example of an embodiment of the method of the invention, scanning the laser beam 704 cuts the wafer 200 from the front face 400 and singulates the dies 102. Again, since the thickness of the wafer 200 is reduced by the grooves 604, the width S2 of the regions affected by the laser scans can be reduced.

In one example of an embodiment of the method of the invention, the laser beam 704 alters the structure of the wafer 200 over a width less than and included within the width of the grooves 604. In the operation of scribing the wafer 200, the laser beam 704 produces defect regions below the front surface 400. The laser beam 704 is pulsed and scans each of the saw streets in a plurality of scans focused at respective depths in the wafer 200. The defects are caused by the material of the wafer 200 rapidly melting and solidifying again in the focal point of the laser beam.

In one example of an embodiment of the method of the invention, semiconductor dies produced by the method illustrated in FIGS. 4 to 9 have edges 108 and the grooves 604 form undercuts in the edges 108 under the active faces 104. The active faces 104 have widths greater than the back faces 106, since the grooves 604 are cut from the back faces 106 of the semiconductor dies 102. The back faces 106 of the semiconductor dies 102 are attached to support surfaces 112 of die support members 110 with a die attach material. The die attach material flows into the undercuts formed by the grooves 604 and a fillet 116 is formed in the undercut. The fillet 116 is contained within the undercut without the undercut reducing the area of the active face 104 of the semiconductor die 102.

In one example of an embodiment of the method of the invention, cutting the grooves 604 includes mounting the wafer 200 with the front face 400 attached to a front face support element 500 and sawing partially through the wafer 200 from the back face 402. The wafer 200 includes alignment marks on the front face 400, the alignment marks being identifiable through the front face support element 500. Sawing partially through the wafer from the back face 402 is guided by the alignment marks on the front face 400. The alignment marks on the front face 400 also guide the subsequent scanning of the laser beam 704 on the front face 400.

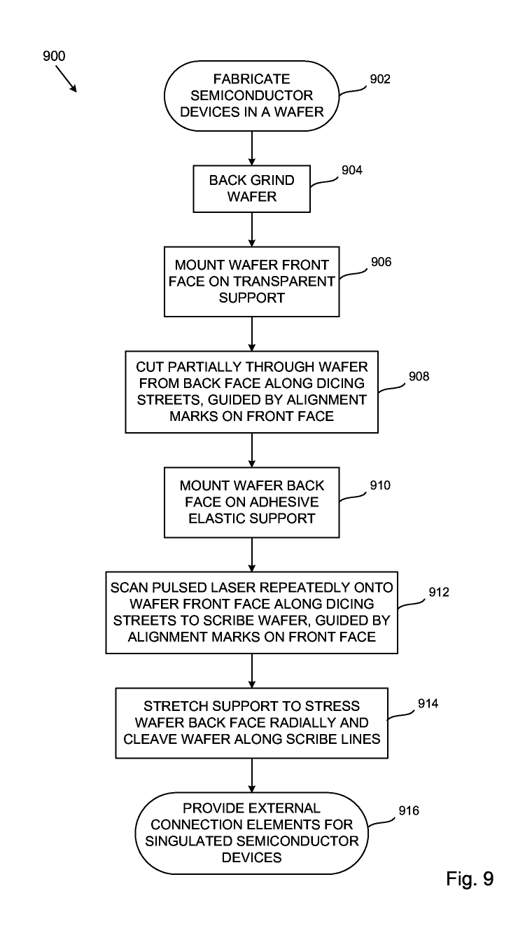

FIG. 9 summarizes steps in a method 900 of producing semiconductor dies in accordance with an example of an embodiment of the invention. The method 900 starts at 902 by providing a wafer 200 in which an array of the semiconductor dies 102 are fabricated. FIG. 4 shows the wafer 200, which is formed from mono-crystalline semiconductor material, such as silicon, or compound semiconductor materials. The active and passive elements of the dies 102 are formed in and on the wafer 200 by steps such as deposition of metals, poly-crystalline semiconductor and other materials, epitaxial growth, etching, patterning, doping, oxidation, which in many cases may be performed by operations from the front face 400 of the wafer. The dies 102 may include electronic components forming integrated circuits (IC) and micro-electromechanical systems (MEMS). The same fabrication steps form alignment marks (not shown) aligned relative to the structure of the semiconductor dies 102.

At 904, the back of the wafer 200 is ground, to reduce the thickness of the wafer. In one example, the wafer 200 was 750 μm thick during the steps of fabricating the semiconductor dies 102 and was 150 μm thick after the back-grind operation.

At 906, the wafer 200 is then mounted with its front face 400 attached to the front face support element 500, as shown in FIG. 5. As shown in FIG. 6, the wafer 200 on its support 500 is then installed in a saw machine including a camera 602 that senses the alignment marks on the front face 400 through the support 500 and any chuck in the machine. The camera 602 enables a guidance module of the machine to guide relative movement of the wafer 200 and a rotating saw blade 600.

The saw blade 600 is used to make cuts in the back face 402 of the wafer 200 to form the grooves 604 part way through the thickness of the wafer 200 in the back face 402 of the wafer and the back faces 106 of the semiconductor dies 102 at 908. The grooves extend along the orthogonal sets of saw streets. The grooves 604 are shown as having a rectangular cross-section but it will be appreciated that the grooves 604 may have any suitable cross-section, which will typically be defined by the cross-section of the saw blade 600. The width of the grooves 604 is approximately 40 μm in this example. The depth of the grooves 604 is approximately half the thickness of the wafer 200 (after back-grinding).

After cutting the grooves 604, the support 500 is removed from the wafer 200, which is then attached by its back face 402 to an adhesive, elastic support 700 at 910. At 912, the laser 702 shown in FIG. 7 scans the laser beam 704 onto the front face 400 within and along the saw streets, guided by the same alignment marks as guided cutting the grooves 604. The laser beam 704 is pulsed and scans each of the saw streets on the front face 400 of the wafer in a plurality of scans focused at respective depths in the wafer 200. The laser beam 704 produces defect regions below the front surface 400 that scribe the wafer over a width less than and included within the width of the grooves 604. In this example of an embodiment of the invention, an ultraviolet (wavelength less than 400 nm) is used. In the operation of scribing the wafer 200, the thickness of the wafer 200 is reduced by the grooves 604, the depth of the laser scribing is up to 20 μm in silicon in this example and the width S2 of the regions affected by the laser scans can be reduced in practice to less than 10 μm, which reduces the wasted width of the dicing streets and the wasted area of the active faces of the dies in the wafer.

At 914, the semiconductor devices 102 are singulated. The singulation operation involves loading the back face 402 of the wafer 200 mechanically to cleave the wafer along the dicing streets. As shown in FIG. 8, loading the back face 402 of the wafer 200 mechanically is performed by sharply stretching the adhesive support element 700 radially, as indicated by the arrows 800, to apply a radial tensile stress to the back face 402. The edges of the semiconductor dies 102 separate along the cleavage lines defined by the scribe lines, as shown at 802.

After the singulation, at 916 external connection elements are provided for the semiconductor dies 102. The external connection elements may be exposed electrical contact elements 118 of the kind shown in FIG. 1, formed from parts of lead frames which also provide die supports 110. Electrical contact elements 120 on the active faces 104 of the semiconductor dies 102 may be electrically connected with the exposed electrical contact elements 118 by bond wires 122, for example. The semiconductor dies 102 may be encapsulated in molding compound 124. One or more dies may be encapsulated in the same package.

It will be appreciated that other ways of providing external electrical contacts may be used, such as ball grid array (BGA) or land grid array (LGA) and with or without redistributed chip packaging (RCP), in which internal electrical contact elements on the active die face are connected to exposed pads on the surface of the package by a redistribution panel to route the signals, and the power and ground connections. It will also be appreciated that semiconductor dies may be packaged in other packages than encapsulation, and alternatively may be supplied bare for incorporation in apparatus which may then be packaged.

In the foregoing specification, the invention has been described with reference to specific examples of embodiments of the invention. It will, however, be evident that various modifications and changes may be made therein without departing from the broader spirit and scope of the invention as set forth in the appended claims.

For example, the semiconductor substrate described herein can be any semiconductor material or combinations of materials, such as gallium arsenide, silicon germanium, silicon-on-insulator (SOI), silicon, monocrystalline silicon, the like, and combinations of the above.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, the word ‘comprising’ or ‘having’ does not exclude the presence of other elements or steps then those listed in a claim. The terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of separating semiconductor dies formed on a wafer, comprising:
providing a semiconductor wafer having front and back faces and an array of semiconductor dies fabricated therein, said semiconductor dies having active faces at said front face of said wafer;
mechanically cutting grooves from said wafer back face partially through said wafer along saw streets between said semiconductor dies; and
singulating said semiconductor dies, including scanning a laser beam on said wafer front face within and along said saw streets.

2. The method of claim 1, wherein scanning said laser beam scribes said wafer from said front face and singulating said semiconductor dies includes loading said wafer mechanically to cleave said wafer along said saw streets.

3. The method of claim 2, wherein singulating said semiconductor dies includes mounting said wafer with said back face attached to a back face adhesive support element after cutting said grooves.

4. The method of claim 3, wherein loading said wafer mechanically includes stretching said back face adhesive support element radially to apply a radial tensile stress to said back face.

5. The method of claim 1, wherein said wafer includes alignment marks on said front face, said alignment marks guiding said scanning of said laser beam.

6. The method of claim 1, wherein said laser beam alters the structure of said wafer over a width less than and included within the width of said grooves.

7. The method of claim 1, wherein said laser beam is pulsed and scans each of said saw streets in a plurality of scans focused at respective depths in said wafer.

8. The method of claim 1, further comprising back-grinding said wafer to produce said back face.

9. The method of claim 1, wherein cutting said grooves includes mounting said wafer with said front face attached to a front face support element and sawing partially through said wafer from said back face.

10. The method of claim 9, wherein said wafer includes alignment marks on said front face, said alignment marks being sensed through said front face support element and guiding said sawing partially through said wafer from said back face.

11. The method of claim 10, wherein said alignment marks on said front face guide said scanning of said laser beam.

12. A method of producing semiconductor devices, comprising:
providing a semiconductor wafer having front and back faces and an array of semiconductor dies fabricated therein, said semiconductor dies having active faces at said front face of said wafer;
mechanically cutting grooves from said wafer back face partially through said wafer along saw streets between said semiconductor dies;
singulating said semiconductor dies, including scanning a laser beam on said wafer front face within and along said saw streets, wherein said singulated semiconductor dies have edges and said grooves form undercuts in said edges under said active faces, and said active faces have widths greater than said back faces;
providing die support members having support surfaces; and
attaching said back faces of said semiconductor dies to said support surfaces with a die attach material, wherein the die attach material flows into said undercut and a fillet is formed in said undercut.

13. The method of claim 12, wherein scanning said laser beam scribes said wafer from said front face and singulating said semiconductor dies includes loading said wafer mechanically to cleave said wafer along said saw streets.

14. The method of claim 13, wherein singulating said semiconductor dies includes mounting said wafer with said back face attached to a back face adhesive support element after cutting said grooves.

15. The method of claim 14, wherein loading said wafer mechanically includes stretching said back face adhesive support element radially to apply a radial tensile stress to said back face.

16. The method of claim 12, wherein said laser beam alters the structure of said wafer over a width less than and included within the width of said grooves.

17. The method of claim 12, wherein said laser beam is pulsed and scans each of said saw streets in a plurality of scans focused at respective depths in said wafer.

18. The method of claim 12, further comprising back-grinding said wafer to produce said back face.

19. The method of claim 12, wherein cutting said grooves includes mounting said wafer with said front face attached to a front face support element and sawing partially through said wafer from said back face.
